(19) United States
(12) Patent Application Publication
(10) Pub. No.: US 2025/0322138 A1
(43) Pub. Date: Oct. 16, 2025

(54) GRAPH-BASED METHOD OF GENERATING ROUTING DATA FOR INTEGRATED CIRCUIT

(71) Applicant: MEDIATEK INC., Hsin-Chu (TW)

(72) Inventors: Chun-Jung Li, Hsinchu City (TW); Chen-Hsing Lo, Hsinchu City (TW); Cheng-Hsun Liu, Hsinchu City (TW); Wei-Liang Ying, Hsinchu City (TW)

(73) Assignee: MEDIATEK INC., Hsin-Chu (TW)

(21) Appl. No.: 18/634,994

(22) Filed: Apr. 14, 2024

(51) Int. Cl. G06F 30/3953

(52) U.S. Cl. CPC G06F 30/3953

(57) ABSTRACT

A graph-based method comprises generating a configuration file according to partition information, and performing a graph-based algorithm according to the configuration file to find a minimum cost path starting from a starting node, passing an intermediate node and terminating at an ending node. The configuration file comprises vertexes and adjacency information.

### BACKGROUND

The invention relates to integrated circuits (IC), and in particular, to a graph-based method of generating routing data for an integrated circuit.

An integrated circuit (IC) includes cells and wires connecting between the cells. Implementation of an integrated circuit comprises dividing the integrated circuit into a plurality of partitions. A partition may be referred to as a block or a module. Dividing the integrated circuit into a plurality of partitions helps to separate distinct functions, achieve feasible size and complexity, meet physical constraints and manage projects. Each partition includes pins for inputting/outputting signals to another partition. Routing is the process of selecting a path between or across multiple partitions and creating a physical connection along the path. In a channelless layout design, a routing path (referred to as a feedthrough) passes through one or more abutting partitions without passing through channels along the edge of the partitions.

The prior art places feedthroughs based on global routing or designer pre-insert. Feedthroughs placement based on global routing utilizes tools to roughly simulate the routing scenarios, increasing routing detours and providing limited controllability. Designer pre-inserted feedthroughs are determined at an early stage and may not match the final situation.

### SUMMARY

According to an embodiment of the invention, a graph-based method comprises generating a configuration file according to partition information, and performing a graph-based algorithm according to the configuration file to find a minimum cost path starting from a starting node, passing an intermediate node and terminating at an ending node. The configuration file comprises vertexes and adjacency information.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a computer system for performing a graph-based method.

FIG. 2 shows a conceptual diagram illustrating the concept of a feedthrough.

FIG. 3 shows a flowchart of a graph-based method of the present invention.

FIG. 4 shows a layout diagram of partitions in an embodiment of the present invention

FIG. 5 shows a graph model according to a configuration file in an embodiment of the present invention.

### DETAILED DESCRIPTION

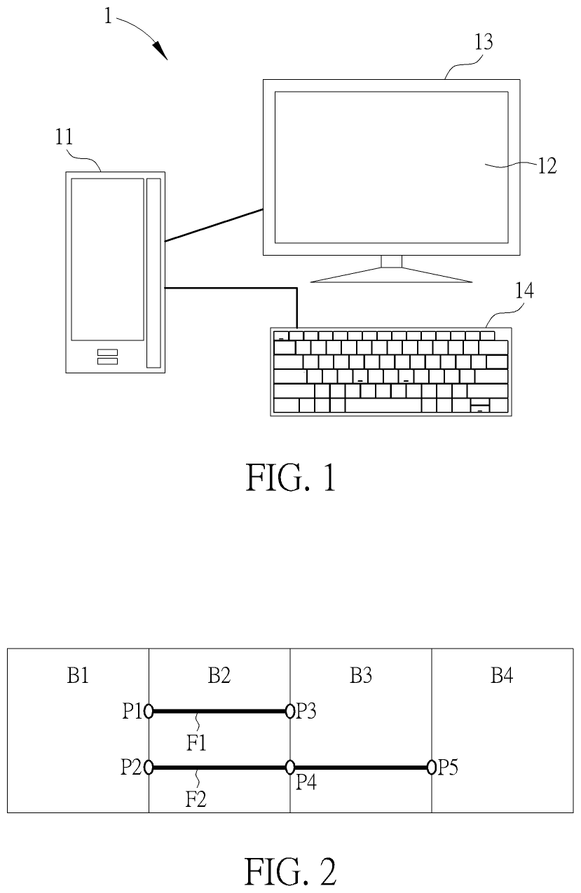

FIG. 2 shows a conceptual diagram illustrating the concept of feedthroughs. FIG. 2 includes partitions B1 to B4 and feedthroughs F1 and F2. The partitions B1 to B4 are abutted sequentially. Each partition may be a block, a standard cell, a group of partitions or a macro, and may include one or more pins. The feedthroughs may be referred to as feedthrough paths or feedthrough nets.

The feedthrough F1 may start from the partition B1, pass through the partition B2, and terminate at the partition B3. The feedthrough F2 may start from the partition B1, passes through the partition B2 and B3 and terminate at the partition B4. The use of the feedthroughs F1 and F2 passing through the abutting partitions is referred to as a channelless layout design. In comparison to a channeled layout design where a routing path passes through a channel along an edge of a partition but not going through the partition, the channelless layout design provides shorter and more consistent routing paths, faster signals transmissions, and enhanced area utilization.

Each partition may be placed in a predetermined location in an integrated circuit (IC) before generating routing data such as the feedthroughs. Each partition may have partition information such as the coordinates, the available pins, and others.

The embodiments of the invention include a graph-based method for generating routing data in an integrated circuit using a graph-based algorithm.

A graph-based algorithm is an algorithm with a set of instructions that traverse a graph. A graph includes vertexes and edges. The vertexes can be also referred to as nodes and the edges are lines that connect any two nodes in the graph. The graph-based algorithm may be a set of instructions that visits nodes of a graph. The graph-based algorithm can be used to find a specific node or the path between two given nodes.

Finding the minimum cost routing path and planning feedthrough can be viewed as minimum cost path problem. By using a graph-based algorithm, the minimum cost path can be efficiently found. Compared to the prior art, the graph-based method of the present invention can effectively control the feedthrough and reduce routing detours.

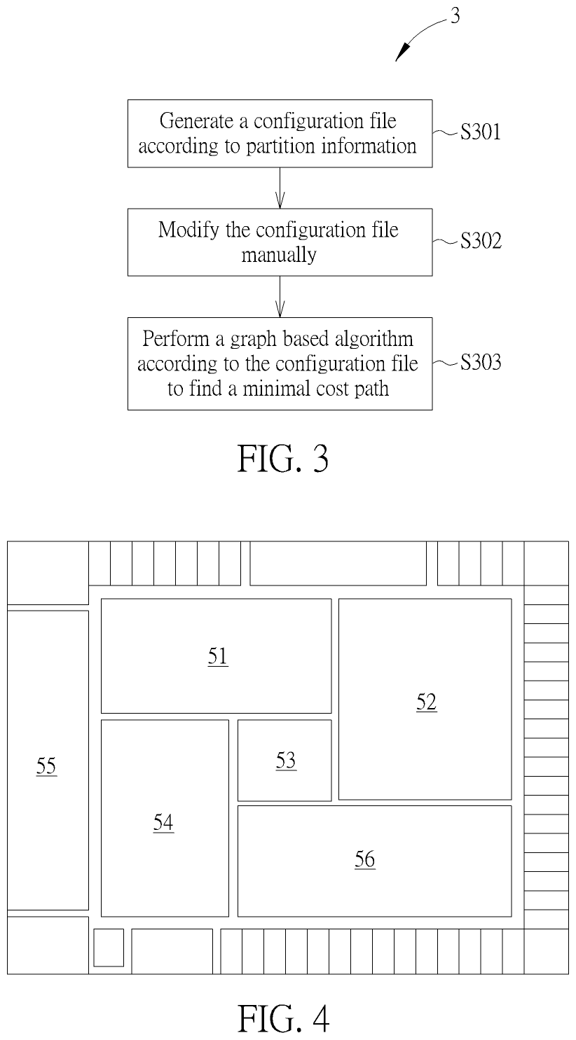

FIG. 3 shows a flowchart of a graph-based method 3 of generating routing data for an integrated circuit according to an embodiment of the invention. The graph-based method 3 comprises Steps S300 to S300. Any reasonable step change or adjustment is within the scope of the disclosure. Steps S301 to S303 are explained as follows:
Step S301: Generate a configuration file according to partition information;
Step S302: Modify the configuration file manually;
Step S303: Perform a graph-based algorithm according to the configuration file to find a minimum cost path.

In Step S301, the partition information can be the location and the relative position of the partitions. By generating configuration files according to partition information, the partition information can be converted into graph elements such as vertexes and edges that can be operated by a graph-based algorithm.

The configuration file comprises vertexes and adjacency information. In some embodiments, the configuration file may be generated according to the partition information by determining the vertexes according to the partition information and importing the adjacency information into the configuration file. Each of the vertexes may be a partition, a standard cell, a group of partitions or a macro. The macro is a pre-placed component and can be a static random-access memory (SRAM) or a read-only memory (ROM).

The vertexes comprise starting nodes, intermediate nodes, and ending nodes. The adjacency information comprises edges, capacities and weights. Each of the edges has a corresponding capacity and weight and directly connects two corresponding vertexes.

The capacities may be positive integers. Each of the capacities represents a quantity of nets allowed for passing through a corresponding edge, wherein a net is a path connecting pins of the vertexes. Specifically, the capacity represents the upper limit of nets allowed for rather than the actual number of nets passing through the corresponding edge. The actual number of nets may be determined by the final result of the graph-based algorithm, and may be less than or equal to the capacity. For example, the capacity may be 10, and the actual number of nets passing through the corresponding edge may be 5.

The weights may be positive integers. Each of the weights is the Manhattan distance of a corresponding edge and is a sum of a distance between X coordinates of the two corresponding connected vertexes and a distance between Y coordinates of the two corresponding connected vertexes. For example, the Manhattan distance between vertexes V1(−1, 4) and V2(1,6) may be 4, equal to the sum of the distance between X coordinates (=1−(−1)=2) and the distance between Y coordinates (=6−4=2). In some embodiments, the weights can also be associated with the power domain. A power domain is a domain whose elements are certain subsets of a domain. In some embodiments, the weight is larger if the corresponding edge passes through different power domains.

In Step S302, after generating the configuration file, the configuration file can be modified manually to meet actual needs. Manual modification can be modify the weight of the edge or modify the capacity of the edge. Step S302 is optional.

In Step S303, the minimum cost path may be found by computing N total weights of N candidate paths starting from the starting node and terminating at the corresponding ending node, N being a positive integer. Each total weight is a sum of the weights of all edges on a corresponding candidate path. The path having the minimum total weight among the N total weights is selected from the N candidate paths as the minimum cost path. For example, if the total weight of a path is 5 and the total weight of another path is 10. The path with the total weight of 5 is the minimum cost path.

The graph-based algorithm can be Bellman Ford algorithm, Breadth First Search (BFS) algorithm, Depth First Search (DFS) algorithm, Floyd Warshall algorithm, Dijkstra's algorithm or other algorithms that find the minimum cost path from a source vertex to all of the other vertexes in a weighted graph. A weighted graph is a graph and each edge of the graph is given a numerical weight.

Minimum cost path problem is an optimization and decision problem to find the cheapest possible way of sending a certain amount of flows through the graph.

The Bellman Ford algorithm is an algorithm used to solve the minimum cost path problem. The Bellman Ford algorithm is also capable of handling graphs in which some of the edge weights are negative numbers. Bellman ford's algorithm can also be used for detecting negative weight cycles as the algorithm converges to an optimal solution in O(V*E) steps, where V and E are the number of vertexes and edges in the graph respectively.

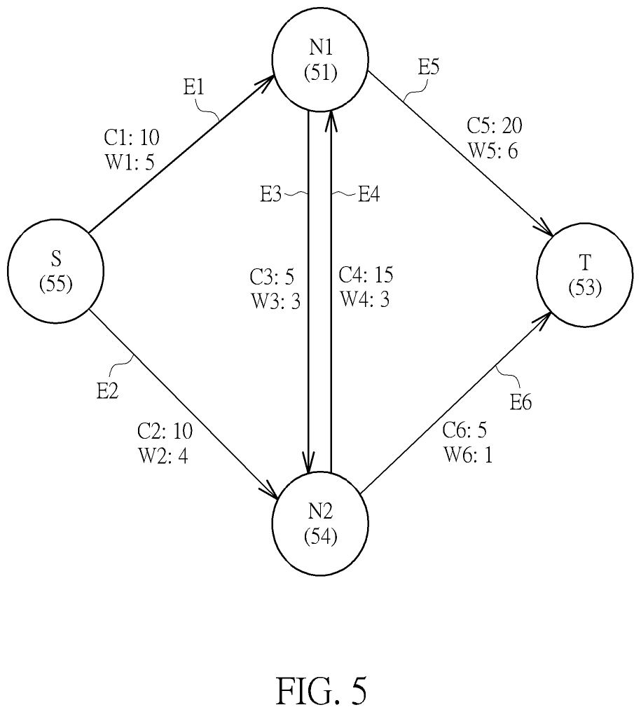

The Bellman Ford algorithm works as follow. First, set the initial weight of each node. The weight of the starting node is set as 0 and the other nodes are set as infinite ∞. Then from the starting node, select an edge connecting the starting node to other nodes, start calculating and updating the weight from the starting node to another node. Calculate the sum of the weight of the original node and the weight of the selected edge. If the calculation result is less than the current value of the weight at the connected node, the weight will be updated to the newly calculated value. Conversely, if the calculation result is greater than the current value of the weight at the connected node, the current value of the weight at the connected node will not be updated. For example, in FIG. 5, select the edge E1, since the sum of the weight of the starting node (=0) and the weight W1 (=5) and is less than infinite (0+5<∞), update the weight of N1 to 5. Repeatedly operate on all nodes. Bellman Ford algorithm may take several rounds to update the weights of all nodes. After updating all nodes, the weight of the ending node is the total weight of the minimum path, thus the minimum path can be found.

Breadth First Search (BFS) algorithm traverses the graph by first checking the current node and then expanding by adding the successors of the current node to the next level. The process is repeated for all nodes in the current level before moving to the next level. The search stops when the minimum cost path is found. The time complexity of BFS is O(V+E) and the space complexity of BFS is O(V). V and E are the number of vertexes and edges in the graph respectively.

Depth First Search (DFS) algorithm solves the minimum cost path problem by traversing the graph by first checking the current node and then moving to one of the current node's successors to repeat the process. If the current node has no successor to check, move back to the predecessor of the current node and continue the process. The search stops when the minimum cost path is found. The time complexity of DES is O(V+E) and the space complexity of DFS is O(V). V and E are the number of vertexes and edges in the graph respectively.

BFS algorithm is more efficient than DFS algorithm in terms of finding the minimum path. Since BFS algorithm only needs to expand the range of search, the path that returns to the ending node first is the minimum path. On the contrary, DFS algorithm needs to run all the paths to find the minimum path. DFS is more suitable to enumerate all possible paths.

Floyd Warshall algorithm finds the minimum cost path between all the pairs of vertexes in a weighted graph. Floyd Warshall algorithm works for both the directed and undirected weighted graphs.

Dijkstra's algorithm is a graph-based algorithm finding the single source shortest path in a graph with non-negative edges. Dijkstra's algorithm starts from the source vertex. For every adjacent vertex adjacent to the current vertex, the distance is updated if it has not been visited before and the distance from the current vertex is less than its current distance. Then we select the next vertex with the least distance and has not been visited. The time complexity of Dijkstra algorithm is O((V+E)*log(E)) and the space complexity of Dijkstra algorithm is O(V+E). V and E are the number of vertexes and edges in the graph respectively.

FIG. 4 shows a layout diagram of partitions in an embodiment of the present invention, and comprises partitions 51 to 55. The partitions are labeled before generating the configuration file.

FIG. 5 shows a graph according to a configuration file in an embodiment of the present invention. In FIGS. 5, S, T, N1 and N2 are vertexes and E1 to E6 are edges. S is a starting node, T is an ending node and N1 and N2 are intermediate nodes. There are two numbers on each edge, the upper number represents the capacity of the edge, and the lower number represents the weight of the edge. For example, in FIG. 5, the capacity C1 of the edge E1 is 10, indicating up to 10 nets are allowed to pass through the edge E1. The weight W1 of the edge E1 is 5, indicating the Manhattan distance of the edge E1. The capacity C2 of the edge E2 is 10, indicating up to 10 nets are allowed to pass through the edge E2. The weight W2 of the edge E2 is 4, indicating the Manhattan distance of the edge E2. The capacity C3 of the edge E3 is 5, indicating up to 5 nets are allowed to pass through the edge E3. The weight W3 of the edge E3 is 3, indicating the Manhattan distance of the edge E3. The capacity C4 of the edge E4 is 15, indicating up to 15 nets are allowed to pass through the edge E4. The weight W4 of the edge E4 is 3, indicating the Manhattan distance of the edge E4. The capacity C5 of the edge E5 is 20, indicating up to 20 nets are allowed to pass through the edge E5. The weight W5 of the edge E5 is 6, indicating the Manhattan distance of the edge E5. The capacity C6 of the edge E6 is 5, indicating up to 5 nets are allowed to pass through the edge E6. The weight W6 of the edge E6 is 1, indicating the Manhattan distance of the edge E6. In some other embodiment, the weight is associated with the power domain. For example, if the node S and the node N1 are in the same power domain and the node N2 is in another power domain, W1 may be greater than W2.

The configuration file is generated according to the partition information. The graph in FIG. 5 is now explained with reference to FIG. 4. In FIG. 5, vertexes S, T, N1 and N2 may correspond to the partitions in FIG. 4. For example, the vertex S can correspond to the partition 55 and the vertex N1 can correspond to the partition 51. The edge E1 can correspond to the nets from the partition 55 to the partition 51. The vertex N2 can correspond to the partition 54 and the vertex T can correspond to the partition 53. The edge E2 in FIG. 5 can correspond to the nets from the partition 55 to the partition 54. The edge E3 in FIG. 5 can correspond to the nets from the partition 51 to the partition 54. The edge E4 in FIG. 5 can correspond to the nets from the partition 54 to the partition 51. The edge E5 in FIG. 5 can correspond to the nets from the partition 51 to the partition 53. The edge E6 in FIG. 5 can correspond to the nets from the partition 54 to the partition 53.

After generating and modifying the configuration file, perform the graph-based algorithm according to the configuration file to find the minimum cost path starting from the starting node, passing the intermediate node and terminating at the ending node. For example, in FIG. 5, the graph-based algorithm is performed to find the minimum cost path starting from the starting node S, passing the intermediate node N1 or N2 and terminating at the ending node T. For example, the total weight of the path starting from the starting node S, passing the intermediate node N1 and terminating at the ending node T may be 11, equal to the sum of the weight W1 (=5) and the weight W5 (=6). The total weight of the path starting from the starting node S, passing the intermediate node N2 and terminating at the ending node T may be 5, equal to the sum of the weight W2 (=4) and the weight W6 (=1). The total weight of the path starting from the starting node S, passing the intermediate node N1 and then passing the intermediate node N2 and terminating at the ending node T may be 9, equal to the sum of the weight W1 (=5), the weight W3 (=3) and the weight W6 (=1). The total weight of the path starting from the starting node S, passing the intermediate node N2 and then passing the intermediate node N1 and terminating at the ending node T may be 13, equal to the sum of the weight W2 (=4), the weight W4 (=3) and the weight W5 (=6). Therefore, the path starting from the starting node S, passing the intermediate node N2 and terminating at the ending node T has the minimum total weight (=4) among the candidate paths, and may be the minimum cost path. The path starting from the starting from the starting node S, passing the intermediate node N1 and then passing the intermediate node N2 and terminating at the ending node T has the second minimum total weight (=9) among the candidate paths, and may be the second minimum cost path. The minimum cost path may be selected as the feedthrough.

In some embodiments, more than one path may be selected as feedthroughs. If the number of required paths is greater than the capacity of the shortest path, for the paths exceeding the capacity, select the second minimum cost path that still has capacity. For example, in FIG. 5, if the number of required paths is 6, and the path starting from the starting node S, passing through E2 and E6 and terminating at the ending node T is the minimum cost path in FIG. 5. Since only up to 5 nets are allowed for passing through E6, the 6th required path may not go through the minimum cost path. Instead, the second minimum cost path starting from the starting node S, passing through the intermediate node N1 and then passing the intermediate node N2 and terminating at the ending node T may be selected for the 6th required path.

While specific example is given in FIG. 5, those skilled in the art would recognize that the graph may incorporate other numbers of vertexes. For example, another graph may include the vertex S, vertex T, and 5 other vertexes. People skilled in the art may apply the principle in the graph-based method 3 to the other graph to determine the minimum cost path.

FIG. 1 shows a computer system 1 for performing the graph-based method 3. The computer system 1 includes a central processing unit (CPU) 11, a display device 13, and an input device 14. The display device 13 and an input device 14 are connected to the central processing unit (CPU) 11. The CPU 11 may perform the graph-based method 3. In some embodiments, the CPU 11 may generate the configuration file according to the partition information and perform the graph-based algorithm according to the configuration file to find the minimum cost path for a routing result. The configuration file and the routing result can be displayed on a graphical user interface (GUI) 12 on the display device 13. Users can interact with the graphical user interface 12 and modify the configuration file manually using the input device 14. The input device 14 can be a mouse, a touch pad or a keyboard.

The graph-based method of the invention is used to determine the minimum cost path, so as to generate routing data such as the feedthrough, providing controllability over feedthrough placement, reducing routing detours and simplifying the routing flow. To be clear, the embodiments of the present invention may use the changeless layout design as examples, but this scope of the present invention does not limit thereto. The methods disclosed in this disclosure may be applied to all layout design, especially to generating the partition information.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A graph-based method of generating routing data for an integrated circuit, the method comprising:
generating a configuration file according to partition information; and
performing a graph-based algorithm according to the configuration file to find a minimum cost path starting from a starting node, passing an intermediate node and terminating at an ending node; and
wherein the configuration file comprises vertexes and adjacency information.

2. The method of claim 1, further comprising modifying the configuration file manually after generating the configuration file.

3. The method of claim 1, wherein generating the configuration file according to the partition information comprises:
determining the vertexes according to the partition information; and
importing the adjacency information into the configuration file.

4. The method of claim 3, wherein the vertexes comprise the starting node, the intermediate node, and the ending node.

5. The method of claim 3, wherein the adjacency information comprises edges, capacities and weights.

6. The method of claim 5, wherein each of the edges directly connects two corresponding vertexes in the vertexes.

7. The method of claim 5, wherein each of the capacities represents a quantity of nets allowed for passing through a corresponding edge in the edges.

8. The method of claim 5, wherein each of the weights is the Manhattan distance of a corresponding edge in the edges.

9. The method of claim 5, wherein each of the weights is associated with a power domain.

10. The method of claim 1, wherein the graph-based algorithm is Bellman Ford Algorithm.

11. The method of claim 1, wherein a total weight of all edges on the minimum cost path is minimal.
